(19) United States
(12) Patent Application Publication
(10) Pub. No.: US 2025/0081409 A1
(43) Pub. Date: Mar. 6, 2025

(54) Heat flow control method and heat flow control system

(71) Applicants: Inventec (Pudong), Technology Corp., Shanghai (CN); Inventec Corporation, Taipei (TW)

(72) Inventors: Chien-Ming Lee, Taipei (TW); Kai-Yang Tung, Taipei (TW); Yu-Hsuan Peng, Taipei (TW)

(73) Assignees: Inventec (Pudong), Technology Corp., Shanghai (CN); Inventec Corporation, Taipei (TW)

(21) Appl. No.: 18/600,768

(22) Filed: Mar. 10, 2024

(30) Foreign Application Priority Data
Sep. 1, 2023 (CN) 202311130742.1

(51) Int. Cl. H05K 7/20; G06F 1/20

(52) U.S. Cl. CPC H05K 7/20836; G06F 1/20; H05K 7/20745

(57) ABSTRACT

A heat flow control method, for a data center cooling system, includes determining a plurality of features corresponding to a current scene of the data center cooling system at a first time point; and determining a plurality of cooling parameters at a second time point according to the plurality of features; wherein the data center cooling system utilizes the plurality of cooling parameters to control heat flow at the second time point; wherein the second time point lags the first time point.

### BACKGROUND OF THE INVENTION

### 1. Field of the Invention

The present invention relates to a heat flow control method and a heat flow control system, and more particularly, to a heat flow control method and a heat flow control system that utilize a deep learning method to determine the heat dissipation parameters.

### 2. Description of the Prior Art

Airflow control is a key technology to enhance the cooling efficiency within a data center or server room. During heat dissipation, the inadvertent blending of cold and hot air can lead to suboptimal cooling performance and increased energy usage. Therefore, the airflow management of modern data centers usually employs strategies like hot and cold tunnel isolation and elevated ventilation floors to reduce improper mixing of hot and cold air. However, in order to ensure that the data center can dissipate heat in a timely manner, it is often more conservative to adopt airflow control, which may cause the data center to be overcooled and consume energy. Under such circumstances, how to improve the airflow of the data center, balance the supply and demand of cooling and reduce energy consumption has become one of the goals of the industry.

### SUMMARY OF THE INVENTION

Therefore, the present invention is to provide a heat flow control method and a heat flow control system to solve the above problem.

The embodiment of the present invention discloses a heat flow control method, for a data center cooling system, which comprises (a) determining a plurality of features corresponding to a current scene of the data center cooling system at a first time point; and (b) determining a plurality of cooling parameters at a second time point according to the plurality of features; wherein the data center cooling system utilizes the plurality of cooling parameters to control heat flow at the second time point; wherein the second time point lags the first time point.

The embodiment of the present invention further discloses a heat flow control system, for a data center cooling system, which comprises a processor; and a memory, coupled to the processor, stores a programing code to indicate the processor to perform a transmission parameter decision method, wherein the transmission parameter decision method comprises: (a) determining a plurality of features corresponding to a current scene of the data center cooling system at a first time point; and (b) determining a plurality of cooling parameters at a second time point according to the plurality of features; wherein the data center cooling system utilizes the plurality of cooling parameters to control heat flow at the second time point; wherein the second time point lags the first time point.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a heat flow control system according to an embodiment of the present invention.

FIG. 2 is a schematic diagram of a data center cooling system according to an embodiment of the present invention.

FIG. 3 is a flowchart of a heat flow control method according to an embodiment of the present invention.

FIG. 4 is a schematic diagram of a deep neural network according to an embodiment of the present invention.

FIGS. 5A-5B are schematic diagrams of a data center cooling system according to an embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

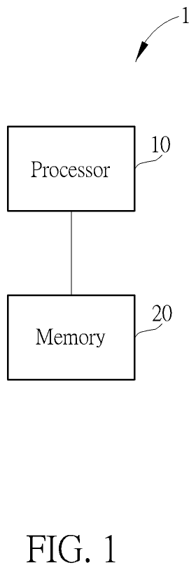

Please refer to FIG. 1. FIG. 1 is a schematic diagram of a heat flow control system 1 according to an embodiment of the present invention. The heat flow control system 1 includes a processor 10 and a memory 20. The memory 20 stores a program code for instructing the processor 10 to execute a heat flow control method to dynamically adjust a plurality of cooling parameters of a data center cooling system and perform heat flow control to balance airflow supply and demand, and reduce power consumption; that is, the cold airflow supply is equal to an airflow demand of the data center cooling system. In an embodiment, the heat flow control system 1 and the executed heat flow control method are suitable for a cooling system of high-performance computing (HPC) devices, such as cloud data center, edge computing centers or single cabinets, but are not limited thereto. It should be noted that the heat flow control system 1 represents the necessary components required to execute the heat flow control method, and its basic structure is well known in the art, and will not be narrated for brevity. Those skilled in the art may add other components as needed, such as the motherboard, the power supply, the memory, proportional-integral-derivative (PID) controller, sensors, etc., but not limited thereto, or may implement the heat flow control system 1 with appropriate devices or equipment. In a preferred embodiment, if the heat flow control method is applied to a single cabinet, the heat flow control method will be executed by the cabinet management controller; if the heat flow control method is applied to multiple cabinets (such as a row or an area), the heat flow control method will be executed by the upper-layer management controller of the multiple cabinets.

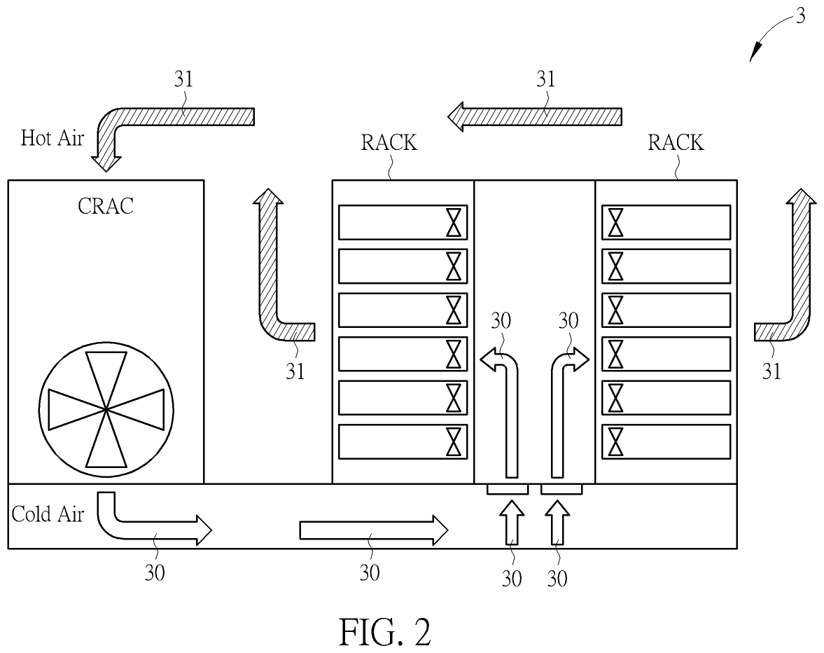

Please refer to FIG. 2. FIG. 2 is a schematic diagram of a data center cooling system 3 according to an embodiment of the present invention. As shown in FIG. 2, the data center cooling system 3 includes a plurality of cabinets RACK and a computer room air conditioning unit (CRAC). The height of the cabinets may be 7U, 14U or 42U, but is not limited thereto. Each server is equipped with server fans and a server room air conditioner is equipped with a CRAC fan, to guide the heat flow. For example, the CRAC fan guides the cold air 30 into the cold tunnel; the server fans guide the cold air 30 into the server, to dissipate heat sources in the server and exhaust the hot air 31 to the hot tunnel. It should be noted that FIG. 2 is merely the embodiment of the present invention, and those skilled in the art may appropriately adjust a fan amount of the CRAC fan and the server fans and configurations of the cold tunnel and the hot tunnel, but is not limited thereto. For example, the data center cooling system 3 may be equipped with a raised perforated floor tile to reduce the mixing of the cold air 30 and the hot air 31.

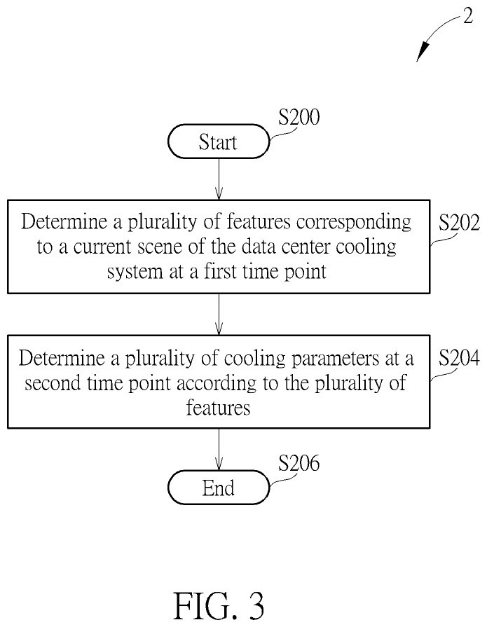

The heat flow control method performed by the heat flow control system 1 in the data center cooling system 3 may be summarized as a process 2, as shown in FIG. 3. The process 2 includes the following steps:
Step S200: Start.
Step S202: Determine a plurality of features corresponding to a current scene of the data center cooling system at a first time point.
Step S204: Determine a plurality of cooling parameters at a second time point according to the plurality of features.
Step S206: End.

According to the process 2, in Step S202, the processor 10 of the heat flow control system 1 may determine the plurality of features corresponding to a current scene (i.e. current environment) of the data center cooling system 3 at the first time point. The plurality of features may include a cold air temperature and a cold air velocity of the cold air generated by the air conditioner in the server room, a server inlet temperature, a server outlet temperature, a server load power and a server fan speed. In another embodiment, the processor 10 may determine the plurality of features corresponding to a past scene (i.e. past environment) of the data center cooling system 3 at the first time point, for example, the plurality of features in the past 20 seconds. It should be noted that the plurality of features of the heat flow control system 1 corresponding to the current scene represent the necessary features required to perform the heat flow control method, and the basic meanings of the plurality of features are well known in the art, and will not be narrated for brevity, and those skilled in the art may add appropriate features to determine the dissipation parameters according to the system requirements, such as a server amount, a plurality of primary component temperatures or a cabinet height, etc.

In Step S204, the processor 10 of the heat flow control system 1 may determine a plurality of cooling parameters at a second time point according to the plurality of features. It should be noted that the second time point lags the first time point. For example, the first time point is a current time point, and the second time point is a time point that the next time the heat flow control system 1 performs the heat flow control according to a plurality of cooling parameters or a time point in the future when performing the heat flow control. The processor 10 may perform a time series prediction model according to the cold air temperature and the cold air velocity, the server inlet temperature, the server outlet temperature, the server load power and the server fan speed, to predict the time series of a plurality of cooling parameters. In an embodiment, a plurality of cooling parameters may be a predicted server inlet temperature and a predicted server fan speed. The heat flow control system 1 may perform the heat flow control according to the predicted server inlet temperature and the result of the time series prediction. In this way, the heat flow control system 1 ensures the server fans and the CRAC fan to operate at the appropriate speed, achieving a balance between airflow supply and demand and reducing the power consumption.

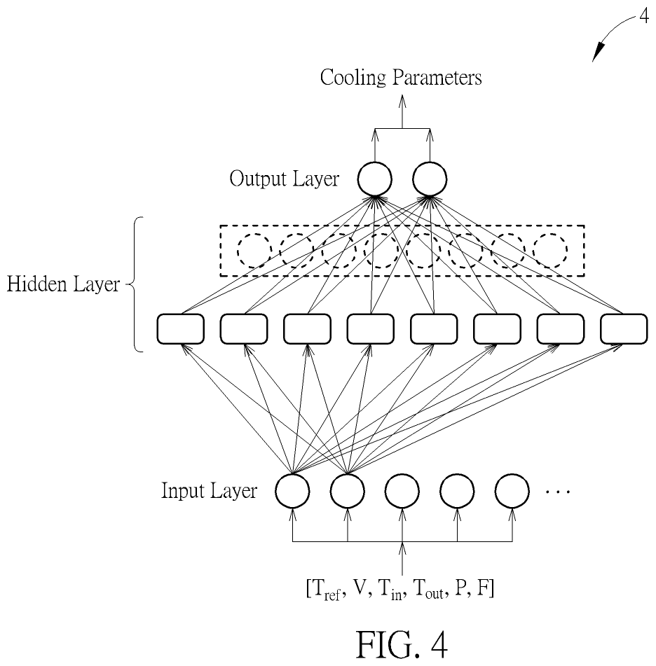

In an embodiment, the time series prediction model may use the architecture of a deep learning method or a reinforcement learning method to predict a plurality of cooling parameters in complex heat flow environments. For example, the time series prediction model may utilize the architecture of a deep neural network (DNN) 4, and FIG. 4 is a schematic diagram of the deep neural network 4 according to an embodiment of the present invention. The deep neural network 4 includes an input layer, a hidden layer and an output layer. The processor 10 may input the cold air temperature T_{ref}, the cold air velocity V, the server inlet temperature Tᵢₙ, the server outlet temperature Tₒᵤₜ, the server load power P and the server fan speed F to the input layer, and obtain a plurality of cooling parameters from the output layer. In this way, the heat flow control system 1 may ensure the server fans and the CRAC fan to operate at the appropriate speed at the second time point according to a plurality of cooling parameters, so as to achieve a balance between airflow supply and demand and reduce the power consumption. It should be noted that the operation principle of the deep neural network should be well known in the art, and will not be narrated for brevity. In addition, the deep learning method or the reinforcement learning method may also employ architectures of a deep belief network (DBN), a convolutional neural network (CNN) and a convolutional deep belief network (CDBN), but is not limited thereto.

In an embodiment, the heat flow control system 1 may obtain 9 sets of the cooling parameters according to the plurality of features and the plurality of fan speeds (e.g., 9 sets such as 20%, 30%-90%) of the CRAC fan. The heat flow control system 1 may calculate 9 sets of the CRAC fan power P_{AF} and the server fan power P_{SF} according to 9 sets of fan speeds and cooling parameters of the CRAC fan. In this way, the heat flow control system 1 may select the lowest total power (the sum of the CRAC fan power P_{AF} and the server fan power P_{SF}) at which the CARC fan is operating.

In an embodiment, regarding the power consumption condition of the heat flow control system 1 of the present invention, please refer to Table 1 and Table 2. Table 1 is the power consumption condition of the heat flow control system 1 to perform the conventional method, and Table 2 is the power consumption condition of the heat flow control system 1 to perform the heat flow control method of the embodiment of the present invention. Comparing Table 1 and Table 2 may be seen that the inlet temperatures of the servers 1-15 of the embodiment of the present invention are 23 degrees, which represents the heat flow balance between the cold air and the hot air. On the other hand, the inlet temperatures of the servers 9-15 of the conventional method are between 24 degrees to 28 degrees, which represents the heat flow imbalance between the cold air and the hot air; that is, the hot air overflows to the inlet of the servers 9-15. Furthermore, since the embodiment of the present invention makes the heat flow of the cold air and the hot air balanced, the fans may operate at a lower fan speed than the conventional method, so that the power consumption is significantly reduced. As can be seen from Table 1 and Table 2, the power consumption of the fans in the embodiment of the present invention is reduced by 38% (1−769.47/474.9) compared with the conventional method.

TABLE 1

| | Inlet | Server | | Power |
|---|---|---|---|---|
| | Temperature | Temperature | Fan Speed | Consumption |
| | Unit | | | |
| | degree | degree | | |
| | Celsius | Celsius | % | Watt |
| Server 1 | 27.79 | 40.4 | 58.80 | 31.99 |
| Server 2 | 27.04 | 40.4 | 57.69 | 30.54 |
| Server 3 | 26.67 | 40.4 | 57.35 | 30.11 |
| Server 4 | 26.31 | 40.5 | 57.30 | 30.05 |
| Server 5 | 25.99 | 40.5 | 57.31 | 30.06 |
| Server 6 | 25.10 | 40.5 | 81.01 | 70.52 |
| Server 7 | 24.36 | 40.5 | 77.61 | 63.33 |
| Server 8 | 23.82 | 40.7 | 76.79 | 61.66 |
| Server 9 | 23.56 | 40.7 | 75.98 | 60.06 |
| Server 10 | 23.51 | 40.7 | 76.31 | 60.72 |
| Server 11 | 23.50 | 40.8 | 75.85 | 59.79 |
| Server 12 | 23.36 | 40.8 | 75.97 | 60.06 |
| Server 13 | 23.29 | 40.9 | 75.49 | 59.10 |
| Server 14 | 23.21 | 40.9 | 75.85 | 59.81 |
| Server 15 | 23.20 | 40.9 | 76.79 | 61.67 |

| | |
|---|---|
| Total Power Consumption | 769.47 |

TABLE 2

| | Inlet | Server | | Power |
|---|---|---|---|---|
| | Temperature | Temperature | Fan Speed | Consumption |
| | Unit | | | |
| | degree | degree | | |
| | Celsius | Celsius | % | Watt |
| Server 15 | 23.98 | 39.5 | 38.07 | 11.55 |
| Server 14 | 23.91 | 40.6 | 39.59 | 12.62 |
| Server 13 | 23.92 | 40.6 | 39.54 | 12.59 |
| Server 12 | 23.79 | 40.5 | 39.07 | 12.25 |
| Server 11 | 23.77 | 40.3 | 38.47 | 11.82 |
| Server 10 | 23.42 | 40.7 | 65.21 | 41.15 |
| Server 9 | 23.48 | 40.8 | 65.05 | 40.90 |
| Server 8 | 23.49 | 40.9 | 65.54 | 41.67 |
| Server 7 | 23.53 | 40.9 | 65.14 | 41.04 |
| Server 6 | 23.51 | 40.9 | 65.37 | 40.65 |
| Server 5 | 23.52 | 40.9 | 64.89 | 41.09 |
| Server 4 | 23.48 | 40.8 | 65.17 | 40.60 |
| Server 3 | 23.49 | 40.9 | 64.86 | 41.09 |
| Server 2 | 23.48 | 40.9 | 65.51 | 40.60 |
| Server 1 | 23.49 | 40.9 | 66.99 | 41.62 |

| | |
|---|---|
| Total Power Consumption | 474.90 |

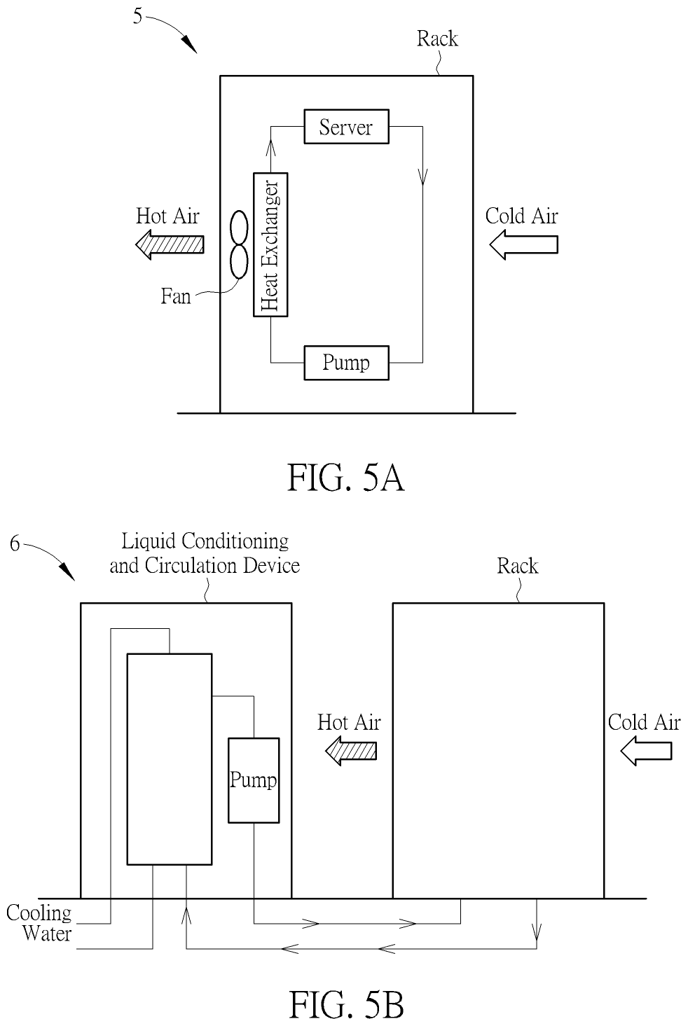

Furthermore, the data center cooling system suitable for the present invention may also include a water-cooled cooling pump, which uses a liquid to take away the heat flow, but is not limited thereto. For example, please refer to FIGS. 5A-5B. FIGS. 5A-5B are schematic diagrams of data center cooling systems 5, 6 according to embodiments of the present invention. The data center cooling systems 5, 6 utilize an internal water-cooling loop and an external water-cooling loop respectively to take away the heat flow of the servers in the rack. The data center cooling systems 5, 6 execute the heat flow control method of the present invention, so that the server fans and the pump operate at the appropriate speed at the second time point, to achieve the balance of airflow supply and demand and reduce the power consumption.

It should be noted that the heat flow control system 1 is the embodiment of the present invention. Those skilled in the art should readily make combinations, modifications and/or alterations on the abovementioned description and examples. The abovementioned description, steps, procedures and/or processes including suggested steps can be realized by means that could be hardware, software, firmware (known as a combination of a hardware device and computer instructions and data that reside as read-only software on the hardware device), an electronic system, or combination thereof. Examples of hardware can include analog, digital and mixed circuits known as microcircuit, microchip, or silicon chip. Examples of the electronic system may include a system on chip (SoC), system in package (SiP), a computer on module (CoM) and the heat flow control system 1. Any of the abovementioned procedures and examples above may be compiled into program codes or instructions that are stored in a memory 20. The memory 20 may include read-only memory (ROM), flash memory, random access memory (RAM), subscriber identity module (SIM), hard disk, or CD-ROM/DVD-ROM/BD-ROM, but not limited thereto. The processor 10 may read and execute the program codes or the instructions stored in the memory 20 for realizing the abovementioned functions.

It should be noted that in the embodiment, the server of the present invention may be used for artificial intelligence (AI) computing, edge computing, and may also be used as a 5G server, a cloud server or a vehicle-to-everything (V2X) server.

In summary, the heat flow control system and the heat flow control method of the present invention predict the cooling parameters at the future time point according to the plurality of features in the current scene or the past scene. In this way, compared to the prior art, the heat flow control method and the heat flow control method of the present invention may ensure the server fans and the CRAC fan to operate at the appropriate speed, to achieve the balance of airflow supply and demand and reduce the power consumption.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heat flow control method, for a data center cooling system, the heat flow control method comprising:
(a) determining a plurality of features corresponding to a current scene of the data center cooling system at a first time point; and
(b) determining a plurality of cooling parameters at a second time point according to the plurality of features;
wherein the data center cooling system utilizes the plurality of cooling parameters to control heat flow at the second time point;
wherein the second time point lags the first time point.

2. The heat flow control method of claim 1, wherein the plurality of features comprise a cold air temperature, a cold air velocity, a server inlet temperature, a server outlet temperature, a server load power, a plurality of primary component temperatures, a server fan speed or a server amount.

3. The heat flow control method of claim 1, wherein the step (b) further comprises:
utilizing a deep learning method to perform a decision-fuse procedure for the plurality of features to generate the plurality of cooling parameters.

4. The heat flow control method of claim 3, wherein the deep learning method adopts at least one of a deep neural network (DNN), a deep belief network (DBN), a convolutional neural network (CNN) and a convolutional deep belief network (CDBN).

5. The heat flow control method of claim 1, wherein the plurality of cooling parameters comprise a predicted server inlet temperature and a predicted server fan speed.

6. A heat flow control system, for a data center cooling system, the heat flow control system comprising:
a processor; and
a memory, coupled to the processor, stores a programing code to indicate the processor to perform a transmission parameter decision method, wherein the transmission parameter decision method comprises:
(a) determining a plurality of features corresponding to a current scene of the data center cooling system at a first time point; and
(b) determining a plurality of cooling parameters at a second time point according to the plurality of features;
wherein the data center cooling system utilizes the plurality of cooling parameters to control heat flow at the second time point;
wherein the second time point lags the first time point.

7. The heat flow control system of claim 6, wherein the plurality of features comprise a cold air temperature, a cold air velocity, a server inlet temperature, a server outlet temperature, a server load power, a plurality of primary component temperatures, a server fan speed or a server amount.

8. The heat flow control system of claim 6, wherein the step (b) further comprises:
utilizing a deep learning method to perform a decision-fuse procedure for the plurality of features to generate the plurality of cooling parameters.

9. The heat flow control system of claim 8, wherein the deep learning method adopts at least one of a deep neural network (DNN), a deep belief network (DBN), a convolutional neural network (CNN) and a convolutional deep belief network (CDBN).

10. The heat flow control system of claim 6, wherein the plurality of cooling parameters comprise a predicted server inlet temperature and a predicted server fan speed.
